(19) United States
(12) Patent Application Publication
(10) Pub. No.: US 2010/0008039 A1
(43) Pub. Date: Jan. 14, 2010

(54) PORTABLE ELECTRONIC DEVICE

(75) Inventors: Yu Chuan Shen, Taiwan (TW); Jih Hung Huang, Taiwan (TW); Chi Yi Liu, Taiwan (TW); Wen Chou Liu, Taiwan (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: ASUSTek Computer Inc., Taipei (TW)

(21) Appl. No.: 12/432,322

(22) Filed: Apr. 29, 2009

(30) Foreign Application Priority Data
Jul. 11, 2008 (TW) 097126442

(51) Int. Cl. H05K 7/00; G06F 1/16

(52) U.S. Cl. 361/679.55

(57) ABSTRACT

The invention discloses a portable electronic device comprising a casing, a first support and a second support. The casing comprises a bottom and a recess formed on the bottom. The recess comprises a first side-portion and a second side-portion opposite to the first side-portion. The first support thereon has a first end and a second end, and the second support thereon has a third end and a fourth end. The first end of the first support is slidably connected between the first and second side-portions. The third end of the second support is pivotally connected to the second end of the first support. The fourth end of the second support is pivotally connected between the first and second side-portions. When the first end of the first support slides along the first and second side-portions, the first support will drive the second support to rotate with respect to the casing.

### BACKGROUND OF THE INVENTION

1. Field of the Invention

The invention relates to a portable electronic device and more particularly to an electronic device with an adjustable underlay-pad.

2. Description of the Prior Art

Please refer to FIG. 1 and FIG. 2. FIG. 1 is an exterior view of a laptop 1 in prior art. FIG. 2 is an exterior view with another view angle of the laptop 1 in FIG. 1. Traditional laptop 1 includes a casing 10 and a display panel 12 pivotally connected to the casing 10. The display panel 12 can be rotated relative to the casing, such that the user can open or close the display panel 12.

As shown in FIG. 2, the bottom 100 of the casing 10 thereon has four underlay-pads 14. The underlay-pads 14 have an anti-skidding function, so the laptop 1 can be placed stably on the table or other plane. However, the underlay-pad 14 of laptop 1 generally is fixed, that means the distance between the bottom of the laptop 1 and the table can not be adjusted at will. Moreover, the use sometimes uses the laptop 1 at a place without a table, so the user puts the laptop 1 on their legs. When the user sits down, the extension direction of the legs usually is not parallel to the horizontal plane. Therefore, the laptop 1 placed on the legs will tend to tilt and can not be placed stably, and it is not convenient for the user.

Therefore, the invention provides a portable electronic device with an adjustable underlay-pad to solve the aforementioned problems.

### SUMMARY OF THE INVENTION

A scope of the invention is to provide a portable electronic device with an adjustable underlay-pad, so that when the user places the portable electronic device, the portable electronic device can be adjusted to a suitable position.

According to an embodiment, the portable electronic device of the invention includes a casing, a first support, and a second support. The casing includes a bottom and a recess formed on the bottom. The recess includes a first side-portion, a second side-portion opposite to the first side-portion, a third side-portion adjacent to the first side-portion, and a fourth side-portion opposite to the third side-portion. The first support includes a first end and a second end, and the second support includes a third end and a fourth end.

In this embodiment, the first end of the first support can be slidably connected to the first side-portion and the second side-portion, and the first side-portion is adjacent to the third side-portion. The third end of the second support is pivotally connected to the second end of the first support. The fourth end of the second support is pivotally connected to the first side-portion and the second side-portion, and the fourth end is near to the fourth side-portion.

When the first end of the first support slides along the first side-portion and the second side-portion, the first support drives the second support to rotate relative to the casing. When the portable electronic device is placed on the legs of the user or other planes, the pivotal connection between the first support and the second support can support the portable electronic device at a suitable height, so that the user can easily operate the portable electronic device.

The advantage and spirit of the invention may be understood by the following recitations together with the appended drawings.

### BRIEF DESCRIPTION OF THE APPENDED DRAWINGS

FIG. 1 is an exterior view of a laptop in prior art.

FIG. 2 is an exterior view with another view angle of the laptop in FIG. 1.

FIG. 3 is an exterior view of a portable electronic device according to an embodiment of the invention.

FIG. 4 is an exterior view with another view angle of the portable electronic device in FIG. 3.

FIG. 5 is an explosion view of some elements of the portable electronic device in FIG. 4.

FIG. 6 is an exterior view of the casing in FIG. 5.

FIG. 7 is an exterior view with another view angle of the casing in FIG. 6.

FIG. 8 is an enlarged view of the first support and the second support in FIG. 5.

FIG. 9 is a schematic diagram illustrating the first support and the second support at a closed status.

FIG. 10 is a schematic diagram illustrating the first support and the second support at an opened status.

FIG. 11 is an exterior view of a casing according to another embodiment of the invention.

FIG. 12 is an exterior view of the first supports and the second supports respectively disposed on the casing in FIG. 11.

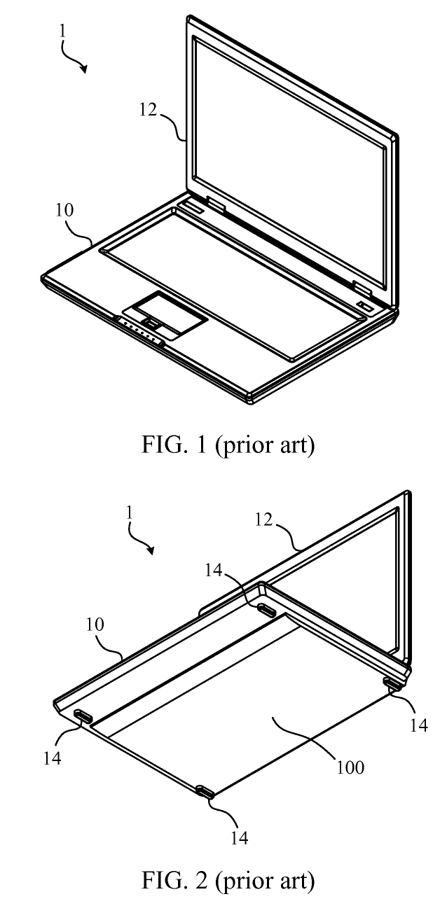

### DETAILED DESCRIPTION OF THE INVENTION

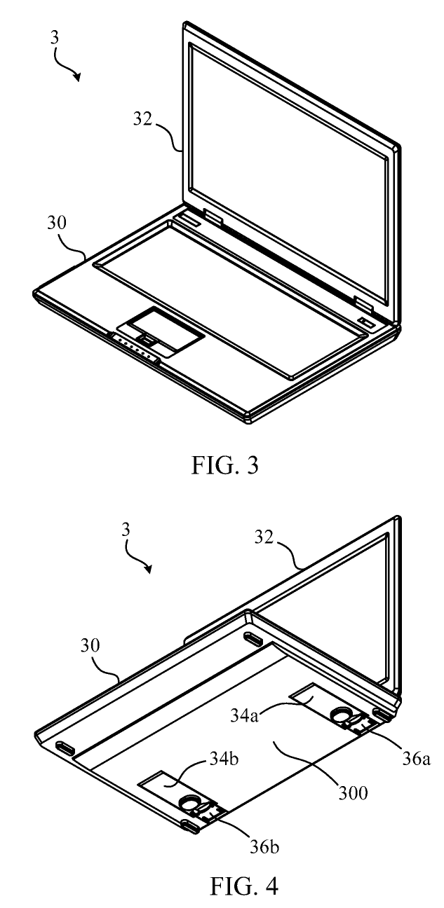

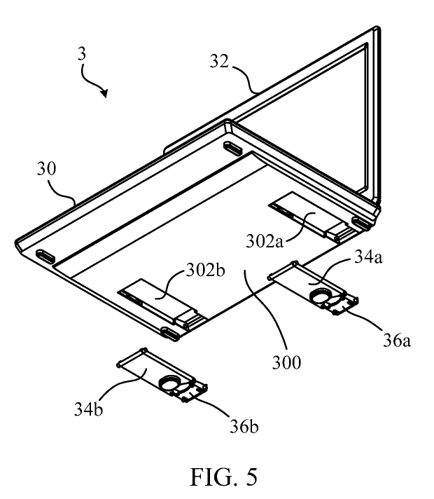

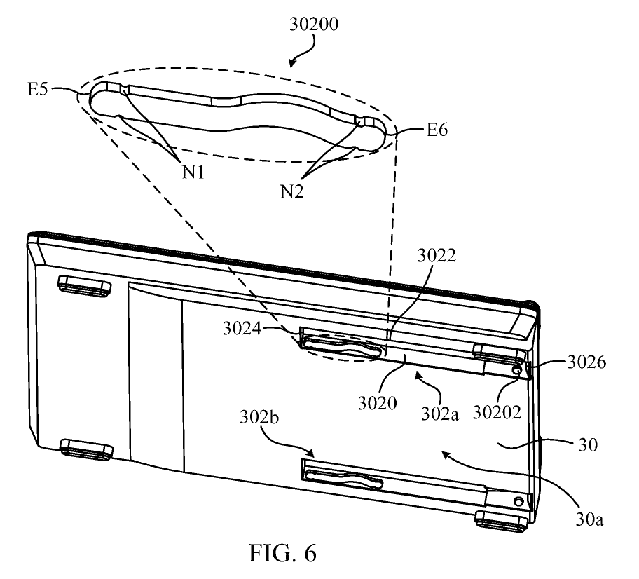

Please refer to FIG. 3 through FIG. 5. FIG. 3 is an exterior view of a portable electronic device 3 according to an embodiment of the invention. FIG. 4 is an exterior view with another view angle of the portable electronic device 3 in FIG. 3. FIG. 5 is an explosion view of some elements of the portable electronic device 3 in FIG. 4. A laptop illustrated in FIG. 3 is an example of the portable electronic device 3, but the portable electronic device is not limited to be the laptop. The portable electronic device 3 includes a casing 30 and a display panel 32 pivotally connected to the casing 30. The display panel 32 can rotate relative to the casing 30, such that the user can open or close the display panel.

Generally, there are necessary software and hardware elements inside the casing 30 of the portable electronic device 3, for example, a central processing unit (CPU), random access memory (RAM), read only memory (ROM), a storage device, a battery for supplying power, and an operation system (OS). The functions of the aforesaid elements are familiar to a person skilled in this art, and these are not described here again.

As shown in FIG. 4 and FIG. 5, the casing 30 includes a bottom 300 and recesses 302a and 302b formed on the bottom 300. The structure of the recess 302a is the same as the recess 302b, so the following description only focuses on the recess 302a.

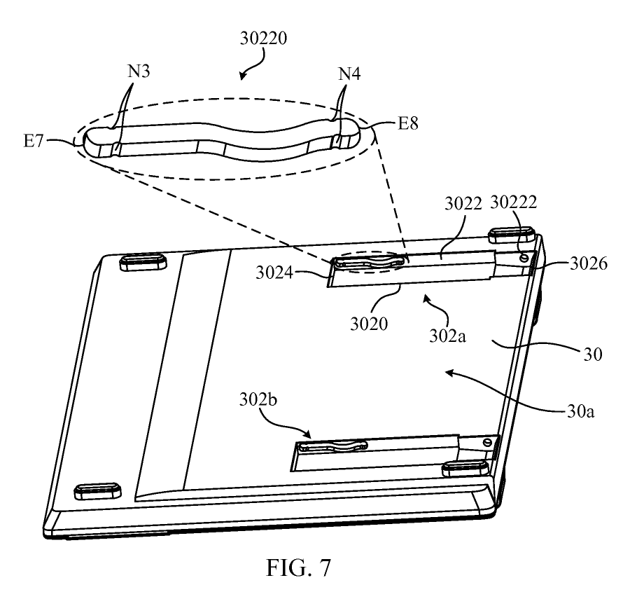

Please refer to FIG. 6 and FIG. 7. FIG. 6 is an exterior view of the casing 30 in FIG. 5. FIG. 7 is an exterior view with another view angle of the casing 30 in FIG. 6. The recess 302a includes a first side-portion 3020, a second side-portion 3022 opposite to the first side-portion 3, a third side-portion 3024 adjacent to the first side-portion 3020, and a fourth side-portion 3026 opposite to the third side-portion 3024. Additionally, the first side-portion 3020 includes a first slide groove 30200 and a first pivot hole 30202, and the second side-portion 3022 includes a second slide groove 30220 and a second pivot hole 30222.

Please refer to FIG. 4 and FIG. 5. The portable electronic device 3 of the invention further includes two first supports 34a and 34b, and two second supports 36a and 36b. The structure of the first support 34a is the same as the first support 34b, and the structure of the second support 36a is the same as the second support 36b. To simplify the description, the following description focuses on the first support 34a and the second support 36a.

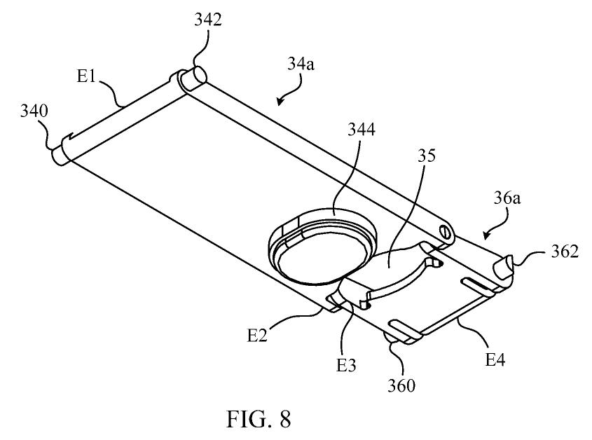

Please refer to FIG. 8. FIG. 8 is an enlarged view of the first support 34a and the second support 36a in FIG. 5. The support 34a includes a first end E1 and the second end E2, and the second support 36a includes a third end E3 and a fourth end E4. The first end E1 of the first support 34a includes a first slide shaft 340 and a second slide shaft 342. The fourth end E4 of the second support 36a includes a first pivot shaft 360 and a second pivot shaft 362. Besides, the first support 34a includes an underlay-pad 344. The underlay-pad 344 is disposed between the first end E1 and the second end E2, for example, the underlay-pad 344 can be disposed near to the second end E2. The underlay-pad 344 has a function of anti-skidding, such that the portable electronic device 3 can be stably placed on the legs of the user or other plane.

Please refer to FIG. 6, FIG. 7 and FIG. 8. When the first support 34a, the second support 36a, and the casing 30 are assembled together, the third end E3 of the second support 36a is pivotally connected to the second end E2 of the first support 34a first of all. Afterward, the first slide shaft 340 of the first support 34a is disposed on the first slide groove 30200 of the casing 30, and the second slide shaft 342 of the first support 34a is disposed on the second slide groove 30220 of the casing 30. Then, the first pivot shaft 360 of the second support 36a is pivotally connected to the first pivot hole 30202 of the casing 30, and the second pivot shaft 362 of the second support 36a is pivotally connected to the second pivot hole 30222 of the casing 30. After the assembling is completed, the first end E1 of the first support 34a is near to the third side-portion 3024 of the recess 302a, and the fourth end E4 of the second support 36a is near to the fourth side-portion 3026 of the recess 302a.

Accordingly, the first end E1 of the first support 34a can be operated by the user to slide along the first side-portion 3020 and the second side-portion 3022 of the recess 302a, to drive the second support 36a to rotate relative to the casing 30. In this embodiment, the first support 34a drives the second support 36a to rotate relative to the casing 30, so the second end E2 of the first support 34a and the third end E3 of the second support 36a protrude from the plane 30a of the casing 30. The portable electronic device can be adjusted by the aforesaid protrusion structure.

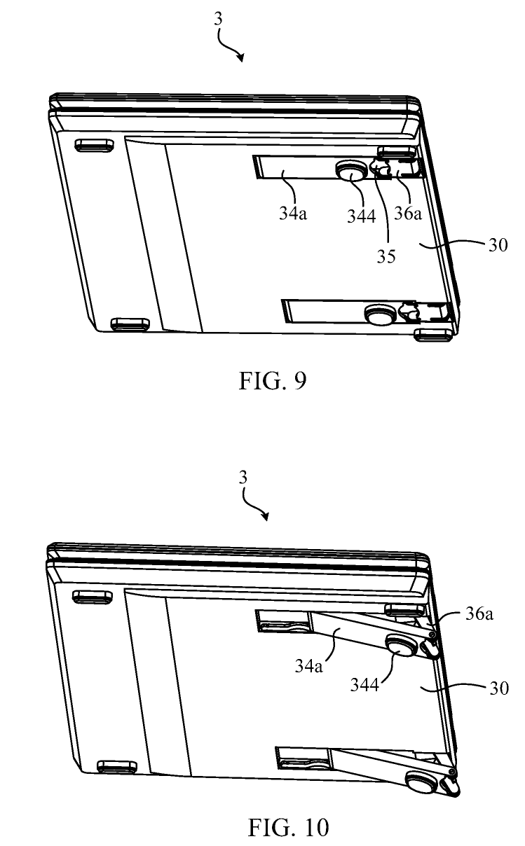

It should be noticed that an operation part 36 is formed on a pivotal connection between the second end E2 of the first support 34a and the third end E3 of the second support 36a, and the operation part 35 can be operated by the user. Please refer to FIG. 9 and FIG. 10. FIG. 9 is a schematic diagram illustrating the first support 34a and the second support 36a at a closed status. FIG. 10 is a schematic diagram illustrating the first support 34a and the second support 36a at an opened status. In this embodiment, the user can operate the operation part 35 to switch the closed status (shown in FIG. 9) of the first support 34a and the second support 36a to the opened status (shown in FIG. 10).

In other words, when the user puts the portable electronic device 3 on the plane, the first support 34a and the second support 36a are at a closed status. When the user puts the portable electronic device 3 on their legs or other inclined plane, the operation part 35 can be pulled by hand, so the first support 34a can slide along the first side-portion 3020 and the second side-portion 3022 of the recess 302a. Furthermore, the second support 36a is driven to rotate relative to the casing 30, and then the first support 34a and the second support 36a are at opened status shown in FIG. 10. Accordingly, the user can adjust the distance between the underlay-pad 344 and the bottom 300 of the casing 30 at will.

Please refer to FIG. 6, FIG. 7, and FIG. 8. The first slide groove 30200 has a fifth end E5 and the sixth end E6. The fifth end E5 has a first clip part N1, and the sixth end E6 has a second clip part N2. The second slide groove 30220 has a seventh end E7 and the eighth end E8. The seventh end E7 has a third clip part N3, and the eighth end E8 has a fourth clip part N4. When the first support 34a and the second support 36a are at a closed status (shown in FIG. 9), the first clip part N1 and the third clip part N3 are respectively used for limiting the movement of the first slide shaft 340 and the second slide shaft 342 of the first support 34a. Therefore, the first support 34a and the second support 36a will be accommodated in the recess 302a.

When the first support 34a and the second support 36a are at an opened status (shown in FIG. 10), the second clip part N2 and the fourth clip part N4 are respectively used for limiting the movement of the first slide shaft 340 and the second slide shaft 342 of the first support 34a. Therefore, the first support 34a and the second support 36a pivotally connected to the first support 34a both keep a support status, and furthermore the portable electronic device 3 can be placed stably on the legs of the user or other surface. In this embodiment, the first support 34a will drive the second support 36a to rotate an angle relative to the casing. For example, the angle is larger than or equal to 90 degrees, so the second support 36a leans again the fourth side-portion 3026 of the recess 302a. The first slide shaft 340 and the second slide shaft 342 of the first support 34a are fixed in the recess 302a by the second clip part N2 and the fourth clip part N4. Therefore, the first support 34a and the second support 36a constitute a support structure of the portable electronic device 3, so the portable electronic device 3 can be placed stably on the legs of the user or other plane.

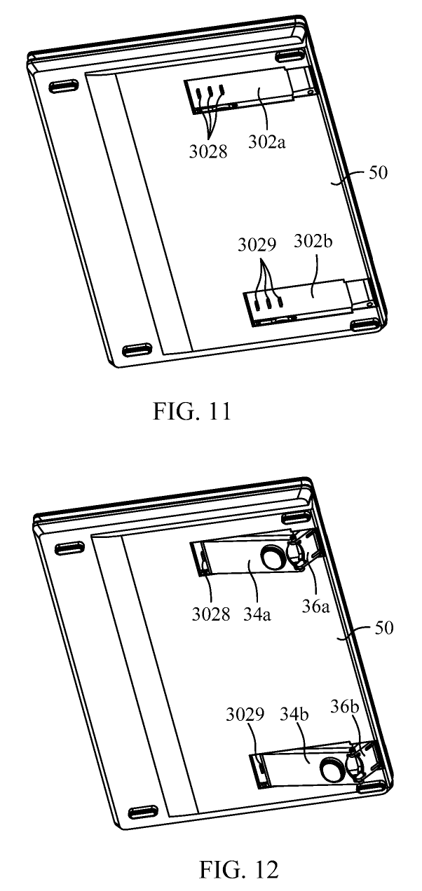

Please refer to FIG. 11 and FIG. 12. FIG. 11 is an exterior view of a casing 50 according to another embodiment of the invention. FIG. 12 is an exterior view of the first supports 34a and 34b and the second supports 36a and 36b respectively disposed on the casing 50 in FIG. 11. The main difference between the aforesaid casing 30 and the casing 50 is that the recess 302a has three block parts 3028 shown in FIG. 11, and the recess 302b also has three block parts 3029 shown in FIG. 11. When the first supports 34a and 34b slide respectively relative to the recesses 302a and 302b, the block parts 3028 and 3029 are respectively used for limiting the movement of the first supports 34a and 34b. In this embodiment, the user can adjust the distance between the underlay-pad and the bottom of the electronic device by the block parts 3028 and 3029, and the opened status shown in FIG. 12 is only one of all possible statuses possible. The amount and the positions of the block parts 3028 and 3029 should be noted that they can be designed at will. If the amount of the block parts 3028 and 3029 are larger, and the positions of the block parts 3028 and 3029 are arranged more tightly, the distance between the underlay-pad and the bottom of the electronic device can be more finely adjusted.

When the user puts the portable electronic device on their legs or other plane, the user can utilize the movable support of the invention to adjust the difference between the underlay-pad and the bottom of the electronic device, that is, the height of the portable electronic device is adjustable. Therefore, the portable electronic device of the invention can be adjusted to be suitable for operation of the user. Additionally, the portable electronic device of the invention further includes block parts, so the height of the portable electronic device can be finely adjusted, and it is more convenient for the user.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A portable electronic device, comprising:
a casing, comprising a bottom and a recess formed on the bottom, the recess comprising a first side-portion, a second side-portion, a third side-portion, and a fourth side-portion;
a first support, comprising a first end and a second end, the first end being slidably connected to the first side-portion and the second side-portion and disposed near to the third side-portion; and
a second support, comprising a third end and a fourth end, the third end being pivotally connected to the second end of the first support, the fourth end being pivotally connected to the first side-portion and the second side-portion and disposed near to the fourth side-portion.

2. The portable electronic device of claim 1, wherein the first side-portion comprises a first slide groove and a first pivot hole, the first end comprises a first slide shaft, the fourth end comprises a first pivot shaft, the first slide shaft is disposed in the first slide groove, the first pivot shaft is pivotally connected to the first pivot hole.

3. The portable electronic device of claim 2, wherein the first slide groove comprises a fifth end and a sixth end, the fifth end comprises a first clip part, the sixth end comprises a second clip part, and the first clip part and the second clip part are respectively utilized for limiting the movement of the first slide shaft.

4. The portable electronic device of claim 1, wherein the second side-portion comprises a second slide groove and a second pivot hole, the first end comprises a second slide shaft, the fourth end comprises a second pivot shaft, the second slide shaft is disposed in the second slide groove, the second pivot shaft is pivotally connected to the second pivot hole.

5. The portable electronic device of claim 4, wherein the second slide groove comprises a seventh end and an eighth end, the seventh end comprises a third clip part, the eighth end comprises a fourth clip part, the third clip part and the fourth clip part are respectively utilized for limiting the movement of the second slide shaft.

6. The portable electronic device of claim 1, wherein the recess comprises a block part, when the first support slides relative to the recess, the block part can limit the movement of the first end of the first support.

7. The portable electronic device of claim 1, wherein the first support comprises an underlay-pad, the underlay-pad is disposed between the first end and the second end.

8. The portable electronic device of claim 1, wherein an operation part is formed on a pivotal connection between the second end of the first support and the third end of the second support.
